(19) United States
(12) Patent Application Publication
(10) Pub. No.: US 2026/0271247 A1
(43) Pub. Date: Sep. 10, 2026

(54) COOLING STRUCTURE FOR SWITCHING POWER SUPPLY

(71) Applicant: SEA SONIC ELECTRONICS CO., LTD., Taipei (TW)

(72) Inventors: Chien-Tung LAN, Taipei (TW); Chih-Sheng CHANG, Taipei (TW); Chih-Chieh TSAI, Taipei (TW); Sheng-Chien CHOU, Taipei (TW)

(21) Appl. No.: 19/071,502

(22) Filed: Mar. 5, 2025

(51) Int. Cl. H05K 7/20

(52) U.S. Cl. CPC H05K 7/20909; H05K 7/20945

(57) ABSTRACT

A cooling structure for switching power supply, including a transformer, a front-end circuit, a rear-end circuit, at least one cooling fan, a plurality of temperature sensors and a temperature control module. One of the temperature sensors arranged corresponding to the front-end circuit provides a first temperature control factor by sensing a temperature of the front-end circuit, and one of the temperature sensors arranged corresponding to the rear-end circuit provides a second temperature control factor by sensing a temperature of the rear-end circuit. The temperature control module controls a rotation speed of the at least one cooling fan based on the first temperature control factor and the second temperature control factor, wherein the first temperature control factor makes the rotation speed of the at least one cooling fan greater than or equal to zero.

### FIELD OF THE INVENTION

The invention relates to a cooling structure for a switching power supply, specifically the cooling structure that incorporates the heat dissipation of a front-end circuit into a control factor for driving a fan.

### BACKGROUND OF THE INVENTION

Currently, power supplies on the market are equipped with temperature protection mechanisms, such as overheating power off, cooling fans, etc., such as TW 201839268A. However, the current temperature protection mechanism is generally based on the temperature rise state of the secondary circuit of the transformer to determine the start-up, and the aforementioned temperature protection mechanism sets a temperature sensor in the secondary circuit of the transformer. When the secondary circuit is running, the components generate heat, and the temperature sensor senses the temperature of the secondary circuit. Once the detection result of the temperature sensor reaches the full-speed heat dissipation condition, the cooling fan is triggered to perform heat dissipation.

The heat source of the power supply is not only distributed in the secondary circuit, but also when the primary circuit is running, the components of the primary circuit will also generate heat energy. However, the temperature protection mechanism of the current power supplies does not include the primary circuit in the judgment of heat dissipation startup, which means that the components of the primary circuit are not protected from overheating. If the primary circuit fails to dissipate heat effectively, the power loss of the primary circuit will increase, affecting the input voltage. In the current switching power supply architecture with a wide input voltage range, the heat accumulation problem can only be solved by increasing the rated power of the component, which in turn leads to an increase in component cost.

TW M390647U discloses a method for temperature protection of a power supply based on a secondary circuit and ambient temperature. According to the description, although the method for the heat dissipation of the power supply incorporates ambient temperature control, the ambient temperature cannot reflect the primary circuit temperature in real time. In addition, it requires that the corresponding heat dissipation be activated only when the ambient temperature exceeds the condition. As a result, the primary circuit temperature cannot obtain a good heat dissipation effect, affecting the reliability of the power supply.

### SUMMARY OF THE INVENTION

A main object of the invention is to improve the problem that the heat dissipation in the current switching power supply does not include the temperature rise state of the front-end circuit of the transformer as a heat dissipation control factor.

In order to achieve the above object, the invention provides a cooling structure of a switching power supply, comprising a transformer, a front-end circuit connected to a primary circuit of the transformer, a rear-end circuit connected to a secondary circuit of the transformer, at least one cooling fan, a plurality of temperature sensors, and a temperature control module electrically connected to the at least one cooling fan. The at least one cooling fan is configured to provide a cooling airflow for the transformer, the front-end circuit and the rear-end circuit. The temperature sensors are respectively arranged corresponding to the front-end circuit and the rear-end circuit. One of the temperature sensors arranged corresponding to the front-end circuit mainly senses a temperature of the front-end circuit to provide a first temperature control factor, and one of the temperature sensors arranged corresponding to the rear-end circuit mainly senses a temperature of the rear-end circuit to provide a second temperature control factor. The temperature control module obtains the first temperature control factor and the second temperature control factor, and controls a rotation speed of the at least one cooling fan based on the first temperature control factor and the second temperature control factor, wherein the first temperature control factor makes the rotation speed of the at least one cooling fan greater than or equal to zero (0), and the second temperature control factor makes the rotation speed of the at least one cooling fan less than or equal to one (1), wherein zero (0) indicates stop rotation, and one (1) indicates full speed rotation.

In one example, the cooling structure of the switching power supply further includes an optical coupling element connected to one of the temperature sensors corresponding to the primary circuit and the temperature control module.

In one example, the cooling structure of the switching power supply further includes a signal amplifying circuit connected between one of the temperature sensors corresponding to the front-end circuit and the optical coupling element.

In one example, the cooling structure of the switching power supply further includes a signal comparison circuit connected to one of the temperature sensors corresponding to the front-end circuit and the optical coupling element.

In one example, the temperature sensors are respectively a thermistor.

In one example, the temperature control module includes a computing chip, in which at least one computing program is stored, and the at least one computing program controls the rotation speed of the at least one cooling fan based on the first temperature control factor and the second temperature control factor.

In one example, the temperature sensors are arranged in a parallel circuit, and the temperature control module is connected to a parallel node of the parallel circuit, and a voltage signal of the parallel node is a combination of the first temperature control factor and the second temperature control factor.

Through the above-mentioned implementation of the present invention, compared with the conventional method, the following characteristics are possessed: the cooling structure of the present invention is provided with the temperature sensors, the temperature control module of the present invention obtains the first temperature control factor and the second temperature control factor, and drives the rotation of the at least one cooling fan with the first temperature control factor and the second temperature control factor. The first temperature control factor makes the rotation speed of the at least one cooling fan greater than or equal to zero (0), and the second temperature control factor makes the rotation speed of the at least one cooling fan less than or equal to one (1). Therefore, the present invention no longer determines an operation of the at least one cooling fan based solely on the temperature of the rear-end circuit or an internal ambient temperature of the switching power supply, but incorporates the temperature of the front-end circuit as a heat dissipation control factor. Compared with the conventional method, the present invention can more effectively improve the power reliability of the switching power supply.

### BRIEF DESCRIPTION OF THE DRAWINGS

FIG. 1 is a unit diagram of an embodiment of the invention.

FIG. 2 is a unit schematic diagram of a signal comparison circuit according to an embodiment of the invention.

FIG. 3 is a schematic diagram of a signal comparison circuit according to an embodiment of the invention.

FIG. 4 is a unit diagram of a signal amplifying circuit according to an embodiment of the invention.

FIG. 5 is a schematic diagram of a signal amplifying circuit according to an embodiment of the invention.

FIG. 6 is a schematic diagram of parallel arrangement of temperature sensors according to an embodiment of the invention.

### DETAILED DESCRIPTION OF THE PREFERRED EMBODIMENTS

The detailed description and technical content of the invention are as follows, with reference to the accompanying figures:

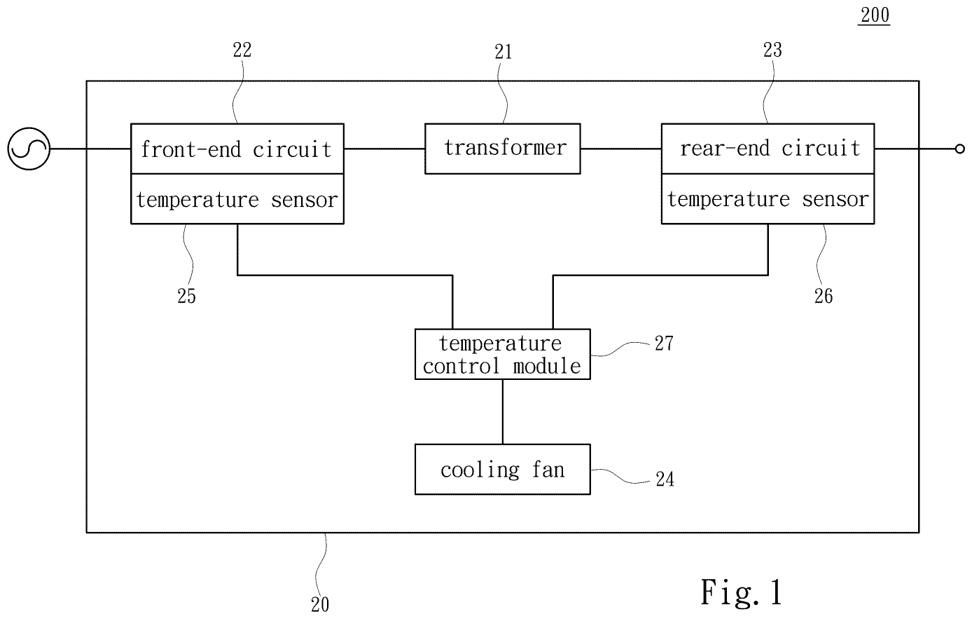

Please refer to FIG. 1. The invention provides a cooling structure 20 for switching power supply 200, including a transformer 21, a front-end circuit 22, a rear-end circuit 23, at least one cooling fan 24, a plurality of temperature sensors 25, 26, and a temperature control module 27. The “front-end” and the “rear-end” referred to herein are defined by their positions relative to the transformer 21. According to common knowledge, the front-end circuit 22 is directly or indirectly electrically connected to a primary circuit of the transformer 21, and the front-end circuit 22 receives external power. The front-end circuit 22 may include a rectifier circuit, a power factor adjustment circuit, an LLC resonant circuit and/or an associated control circuit. Similarly, the rear-end circuit 23 is directly or indirectly electrically connected to a secondary circuit of the transformer 21, and the rear-end circuit 23 outputs power. The rear-end circuit 23 may include at least one power conversion circuit and/or an associated control circuit. The at least one cooling fan 24 is located in a housing of the switching power supply 200. The at least one cooling fan 24 is configured to provide a cooling airflow to a space in the housing of the switching power supply 200. In other words, when the at least one cooling fan 24 is activated, the at least one cooling fan 24 does not dissipate heat for a single circuit, but can provide heat dissipation for the transformer 21, the front-end circuit 22, and the rear-end circuit 23 in the housing. On the other hand, a plurality of ventilation holes are formed on the housing, and the at least one fooling fan can be disposed corresponding to at least one of the ventilation holes.

The temperature sensors 25, 26 are respectively arranged corresponding to the front-end circuit 22 and the rear-end circuit 23. The corresponding arrangement mentioned herein means that the temperature sensors 25, 26 are respectively arranged close to the front-end circuit 22 and the rear-end circuit 23. For example, one of the temperature sensors 25 corresponding to the front-end circuit 22 is disposed close to an electronic component with obvious temperature rise in the front-end circuit 22, one of the temperature sensors 25 provides a first temperature control factor by mainly sensing a temperature of the electronic component. One of the temperature sensors 26 corresponding to the rear-end circuit 23 is disposed close to an electronic component with obvious temperature rise in the rear-end circuit 23, one of the temperature sensors 26 provides a second temperature control factor by mainly sensing a temperature of the electronic component. A relationship between the temperature sensors 25, 26 and the front-end circuit 22 and the rear-end circuit 23 must be such that the temperature of one of the front-end circuit 22 and the rear-end circuit 23 can be sensed.

The temperature control module 27 is electrically connected to the at least one cooling fan 24 and obtains the first temperature control factor and the second temperature control factor. The temperature control module 27 controls a rotation speed of the at least one cooling fan 24 based on the first temperature control factor and the second temperature control factor. The first temperature control factor makes the rotation speed of the at least one cooling fan 24 greater than or equal to zero (0), and the second temperature control factor makes the rotation speed of the at least one cooling fan 24 less than or equal to one (1), wherein zero (0) means stop rotation and one (1) means full speed rotation.

At the beginning of the operation of the switching power supply 200, the front-end circuit 22 and the rear-end circuit 23 are powered on and temperatures rise respectively. The temperature control module 27 controls the at least one cooling fan 24 based on the first temperature control factor and the second temperature control factor, so that when the temperature of the front-end circuit 22 (i.e., the power factor adjustment circuit) rises significantly, the heat dissipation can be performed in advance to avoid the accumulation of waste heat in subsequent work and seriously affect the power reliability of the switching power supply 200. A control basis of the aforementioned advanced heat dissipation comes from the first temperature control factor. A speed control of the at least one cooling fan 24 corresponding to the first temperature control factor is not mainly aimed at full speed operation, but to make the at least one cooling fan 24 rotate for appropriate heat dissipation. The second temperature control factor is used as a starting basis for determining whether the temperature of the rear-end circuit 23 rises after startup and needs to be cooled. A control generated by the temperature control module 27 based on the first temperature control factor and the second temperature control factor can be stepped control or linear control. In terms of step control, the temperature control module 27 divides the rotation speed of the at least one cooling fan 24 into a plurality of stages, and the at least one cooling fan 24 operates at one of a plurality of predefined rotation speeds. In terms of linear control, the temperature control module 27 allows the rotation speed of the at least one cooling fan 24 to present a continuous linear change.

As can be seen from the foregoing, the cooling structure 20 of the invention no longer determines an operation of the at least one cooling fan 24 based solely on the temperature of the rear-end circuit 23, but incorporates a temperature rise condition of the front-end circuit 22 to perform speed control so that the front-end circuit 22 can be effectively cooled. Compared with conventional methods, the invention can improve the power reliability of the switching power supply 200. In addition to the above, the invention incorporates the temperature of the front-end circuit 22 into the speed control, and also achieves pre-cooling of the rear-end circuit 23 to a certain extent.

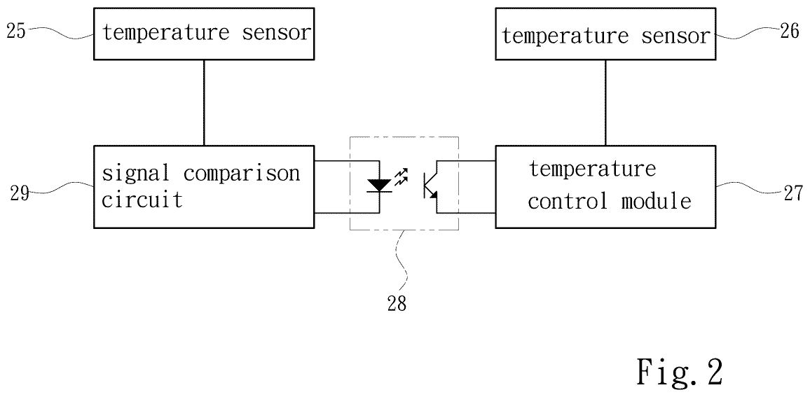

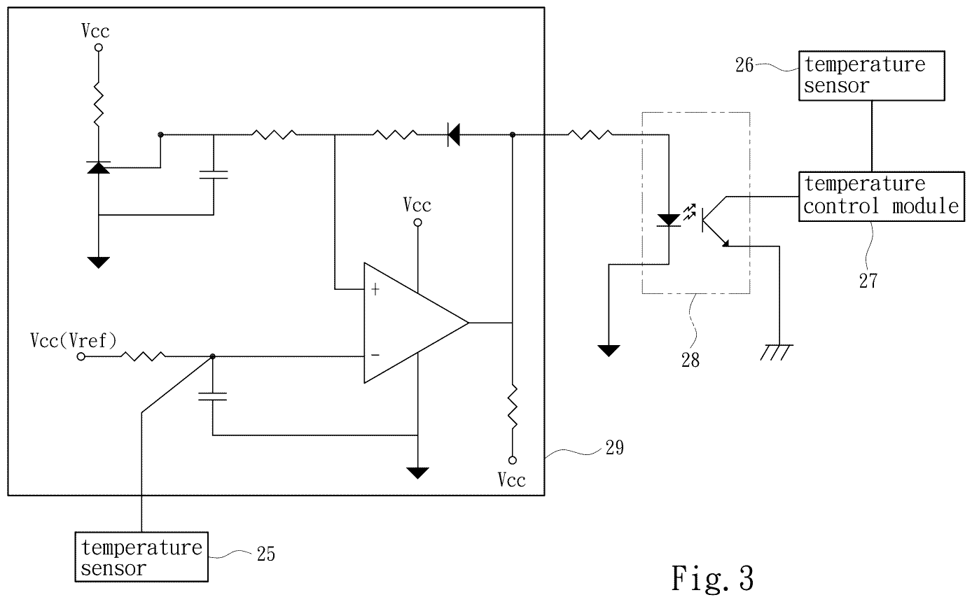

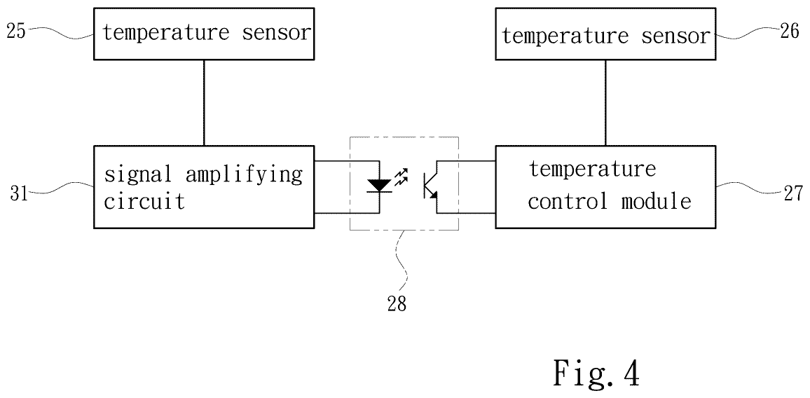

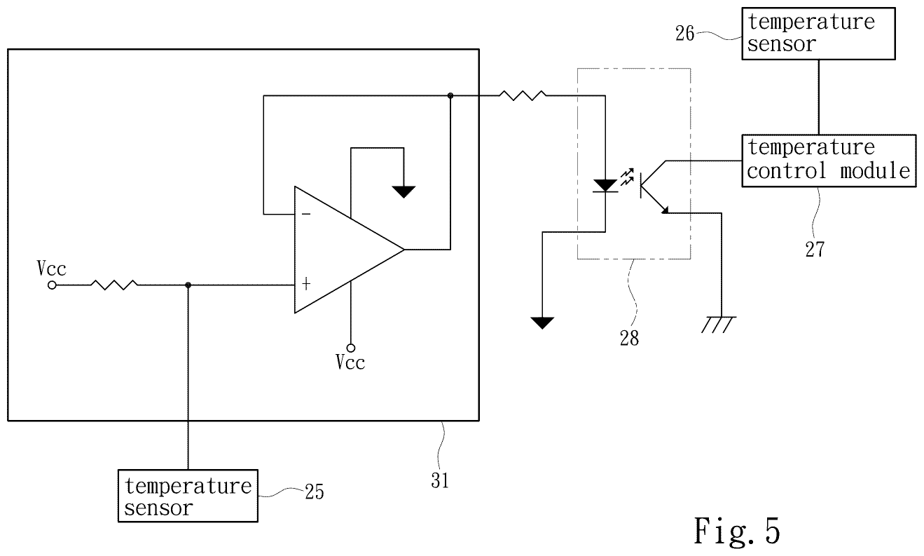

In one example, the temperature sensors 25, 26 of the invention are respectively a thermistor, and a plurality of thermistors respectively sense the temperature of the front-end circuit 22 and the temperature of the rear-end circuit 23, and change their own resistance values as the aforementioned temperatures change, thereby allowing the temperature control module 27 to receive different voltage signals and control the at least one cooling fan 24 according to the different voltage signals. Please refer to FIG. 2, FIG. 3, FIG. 4 and FIG. 5. In one example, the cooling structure 20 includes an optical coupling element 28 connecting one of the temperature sensors 25 corresponding to the front-end circuit 22 and the temperature control module 27. The optical coupling element 28 provides an isolation effect for one of the temperature sensors 25 corresponding to the front-end circuit 22 and the temperature control module 27. In one embodiment, as shown in FIG. 2, the cooling structure 20 further includes a signal comparison circuit 29 connected between one of the temperature sensors 25 corresponding to the front-end circuit 22 and the optical coupling element 28. The signal comparison circuit 29 compares the first temperature control factor (i.e., voltage signal) generated by one of the temperature sensors 25 corresponding to the front-end circuit 22 with a reference voltage (Vref), and then transmits a comparison result to the optical coupling element 28. Please refer to FIG. 3 for a circuit diagram of an example of the signal comparison circuit 29. In another example, see FIG. 4, the cooling structure 20 includes a signal amplifying circuit 31 connected between one of the temperature sensors 25 corresponding to the front-end circuit 22 and the optical coupling element 28. The signal amplifying circuit 31 amplifies a signal of one of the temperature sensors 25 corresponding to the front-end circuit 22 and transmits it to the optical coupling element 28, thereby facilitating a control of the temperature control module 27 at a rear-end and avoiding the problem that a signal of the first temperature control factor is not obvious and affects the subsequent control. Please refer to FIG. 5 for a circuit diagram of an example of the signal amplifying circuit 31. In one example, the signal comparison circuit 29 and the signal amplifying circuit 31 may be implemented together. When implemented, the signal amplifying circuit 31 may be implemented first and the signal comparison circuit 29 may be implemented later.

The temperature control module 27 of the invention can be implemented by an analog temperature control circuit or a digital temperature control circuit. In an example of the digital temperature control circuit, the temperature control module 27 includes a computing chip, and at least two pins of the computing chip are respectively connected to the temperature sensors 25, 26. At least one computing program is stored in the computing chip. The at least one computing program is stored in a memory of the computing chip. The method of storing the at least one computing program in the computing chip is a common technique in the field and will not be described in detail here. When the computing chip runs the at least one computing program, the computing chip performs computing based on voltages of the at least two pins connected to the temperature sensors 25, 26 to determine the rotation speed of the at least one cooling fan 24.

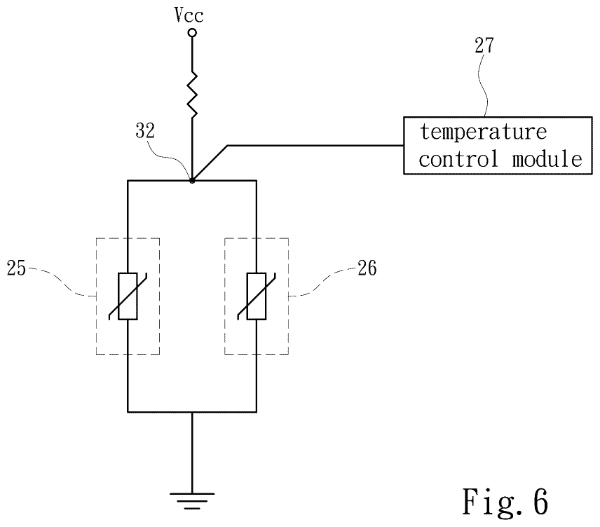

In one example, please refer to FIG. 1 and FIG. 6, the temperature sensors 25, 26 are implemented in a parallel circuit, and the temperature control module 27 is connected to a parallel node of the parallel circuit (i.e., one of a plurality of nodes 32 generated by a parallel connection of the temperature sensors 25, 26), and controls the rotation speed of the at least one cooling fan 24 with a voltage signal of the parallel node. The voltage signal of the parallel node is a combination of the first temperature control factor and the second temperature control factor.

What is claimed is:

1. A cooling structure for switching power supply:
a transformer:
a front-end circuit, connected to a primary circuit of the transformer;
a rear-end circuit, connected to a secondary circuit of the transformer;
at least one cooling fan, arranged corresponding to the transformer, the front-end circuit and the rear-end circuit to provide a cooling airflow;
a plurality of temperature sensors, respectively arranged corresponding to the front-end circuit and the rear-end circuit, one of the temperature sensors corresponding to the front-end circuit providing a first temperature control factor by mainly sensing a temperature of the front-end circuit, one of the temperature sensors corresponding to the rear-end circuit providing a second temperature control factor by mainly sensing a temperature of the rear-end circuit; and
a temperature control module, electrically connected to the at least one cooling fan to obtain the first temperature control factor and the second temperature control factor, the temperature control module controlling a rotation speed of the at least one cooling fan based on the first temperature control factor and the second temperature control factor, wherein the first temperature control factor makes the rotation speed of the at least one cooling fan greater than or equal to zero (0), and the second temperature control factor makes the rotation speed of the at least one cooling fan less than or equal to one (1), wherein zero (0) indicates stop rotation, and one (1) indicates full speed rotation.

2. The cooling structure for switching power supply as claimed in claim 1, further comprising an optical coupling element connected to one of the temperature sensors corresponding to the primary circuit and the temperature control module.

3. The cooling structure for switching power supply as claimed in claim 2, further comprising a signal amplifying circuit connected between one of the temperature sensors corresponding to the front-end circuit and the optical coupling element.

4. The cooling structure for switching power supply as claimed in claim 2, further comprising a signal comparison circuit connected to one of the temperature sensors corresponding to the front-end circuit and the optical coupling element.

5. The cooling structure for switching power supply as claimed in claim 1, wherein the temperature sensors are respectively a thermistor.

6. The cooling structure for switching power supply as claimed in claim 1, wherein the temperature control module comprises a computing chip, in which at least one computing program is stored, and the at least one computing program controls the rotation speed of the at least one cooling fan based on the first temperature control factor and the second temperature control factor.

7. The cooling structure for switching power supply as claimed in claim 1, wherein the temperature sensors are arranged in a parallel circuit, and the temperature control module is connected to a parallel node of the parallel circuit, and a voltage signal of the parallel node is a combination of the first temperature control factor and the second temperature control factor.
